(19) United States
(12) Patent Application Publication
(10) Pub. No.: US 2007/0013041 A1
(43) Pub. Date: Jan. 18, 2007

(54) Flexible wiring board and flex-rigid wiring board

(76) Inventors: Satoru Ishigaki, Kawasaki-shi, Kanagawa (JP); Taro Nagasaka, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/558,281

(22) PCT Filed: May 31, 2004
(86) PCT No.: PCT/JP04/07858

§ 371 Date: Nov. 28, 2005

Related U.S. Application Data
(60) Provisional application No. 60/477,959, filed on Jun. 13, 2003.

(30) Foreign Application Priority Data
Jun. 2, 2003 (JP) 2003-156633

(51) Int. Cl. H01L 23/02

(52) U.S. Cl. 257/686

(57) ABSTRACT

The invention provides a flexible wiring board for repeated folding sections which exhibits excellent folding endurance, and a flex-rigid wiring board comprising the flexible wiring board as a section thereof. The flexible wiring board for repeated folding sections of the invention comprises a wiring patterned base film layer (11), a flexible insulating material layer (12) covering the layer (11), and a cover film layer (13) covering the layer (12).

### CROSS-REFERENCES TO RELATED APPLICATIONS

This application claims benefit under 35 U.S.C. §119(e) to U.S. Provisional Application Ser. No. 60/477,959, filed Jun. 13, 2003.

### TECHNICAL FIELD

The present invention relates to a flexible wiring board for repeated folding sections, and more specifically, it relates to a flex-rigid wiring board provided with a flexible wiring board for repeated folding sections which exhibits excellent folding endurance.

### BACKGROUND ART

Printed wiring boards having rigid sections formed on portions of wiring patterned flexible printed wiring boards are commonly known as flex-rigid wiring boards (FIG. 1). A flex-rigid wiring board comprises relatively hard rigid sections on which electronic parts are mounted, and foldable (folding) flexible sections for electrical connection between the rigid sections or between the rigid sections and electronic parts. The foldable flexible sections of such flex-rigid wiring boards afford a great deal of freedom of spatial arrangement, and can also be situated in a manner straddling movable parts and fixed parts (FIG. 2).

Flex-rigid wiring boards usually have a structure obtained by using an adhesive sheet to laminate a board forming the rigid sections, and a flexible board obtained by attaching an adhesive-coated cover film, known as a cover-lay film, directly onto the metal foil layer of an insulating base material having a pattern circuit formed therein by a metal foil layer. The insulating base material is made of a flexible film which is normally a polyimide resin, polyethylene terephthalate resin or the like.

When using conventional flex-rigid wiring boards as substrates for folding cellular phones, for example, the flexible section straddling the folding part must undergo tens and even hundreds of thousands of folding actions, and must therefore have high folding endurance and flexibility. The pattern circuit-containing metal foil layer sections suffer fatigue wear, resulting in cracks and pattern circuit breaks.

For this reason it has been proposed in the past, for situations requiring repeated folding, to utilize adhesives with high elastic moduli and heat resistance for adhesion between the metal foil layers and insulating base materials in order to prevent generation and propagation of cracks, but the disadvantages of this approach are that the resulting flexible sections are hard and lack flexibility.

When the materials used for construction of the insulating base materials of flex-rigid wiring boards are unsuitable, they may result in poor adaptability for use due to cracking or breaking of the wiring board itself even before fatigue wear of the metal foil layer sections occurs.

Japanese Unexamined Patent Publication HEI No. 7-207211 describes a resist ink composition for flexible printed wiring boards wherein the cured film exhibits excellent pliability, folding strength, adhesion, chemical resistance and heat resistance, but it is not intended to provide improved folding endurance.

Japanese Unexamined Patent Publication No. 2000-109541 discloses a photocuring thermosetting resin composition for solder resist which is suitable for both rigid array boards and flexible wiring boards. However, the composition is not intended to provide improved folding endurance of flexible sections.

It is an object of the present invention to provide a flexible wiring board with excellent repeated folding endurance and a flex-rigid wiring board comprising the flexible wiring board as a section thereof, and in particular, to provide a flex-rigid wiring board which exhibits no cracks or breaks in the metal foil forming the pattern circuit even with repeated folding, and wherein the intervening insulating layer has high adhesive strength to prevent peeling. It is another object of the invention to provide a flex-rigid wiring board with excellent strength, and especially excellent breaking strength between the rigid sections and flexible sections.

According to the present invention, a flex-rigid wiring board comprising an insulating base material, a pattern circuit-forming metal foil layer and an insulating material laminated in that order has a specific construction whereby it is possible to obtain a flex-rigid wiring board having improved folding endurance without sacrificing flexibility of the flexible printed wiring board as a whole, and to obtain a printed wiring board with excellent breaking strength. Specifically, the invention relates to the following aspects [1] to [14].

### SUMMARY OF THE INVENTION

[1] A flexible wiring board for repeated folding sections, which comprises a wiring patterned base film layer (I), a flexible insulating material layer (II) covering the layer (I), and a cover film layer (III) covering the layer (II).

[2] The flexible wiring board for repeated folding sections according to [1] above, wherein the cover film layer (III) is further covered with a flexible insulating material.

[3] The flexible wiring board for repeated folding sections according to [1] above, characterized in that the flexible insulating material layer (II) is a cured heat-curing and/or photocuring resin composition.

[4] The flexible wiring board for repeated folding sections according to [3] above, characterized in that the heat-curing and/or photocuring resin composition contains a biphenol-type epoxy resin.

[5] The flexible wiring board for repeated folding sections according to [4] above, characterized in that the heat-curing and/or photocuring resin composition contains an urethane acrylate.

[6] The flexible wiring board for repeated folding sections according to [1] above, wherein the base film layer (I) is a polyimide.

[7] The flexible wiring board for repeated folding sections according to [1] above, wherein the cover film layer (III) is a polyimide film.

[8] The flexible wiring board for repeated folding sections according to [7] above, wherein the cover film layer (III) is an adhesive-attached polyimide film.

[9] A flex-rigid wiring board provided with a flexible wiring board for repeated folding sections which comprises a wiring patterned base film layer (I), a flexible insulating material layer (II) covering the layer (I), and a cover film layer (III) covering the layer (II).

[10] A flex-rigid wiring board having a rigid section formed on a portion of a flexible wiring board for repeated folding sections which comprises a wiring patterned base film layer (I), a flexible insulating material layer (II) covering the layer (I), and a cover film layer (III) covering the layer (II).

[11] The flex-rigid wiring board according to [10] above, wherein the cover film layer (III) forms part of the rigid section.

[12] The flex-rigid wiring board according to [10] above, wherein the rigid section is formed so as to cover a portion of the cover film layer (III).

[13] The flex-rigid wiring board according to [9] or [10] above, wherein the cover film layer (III) is further covered with a flexible insulating material.

[14] The flex-rigid wiring board provided with a flexible wiring board for repeated folding sections according to [1] or [2] above.

### BRIEF DESCRIPTION OF THE DRAWINGS

FIG. 1 is a plan view of a flex-rigid wiring board.

FIG. 2 is a side view of a folded flex-rigid wiring board.

FIG. 3 is a schematic diagram (plan) of the flexible wiring board test sample of Example 1.

FIG. 4 is a schematic diagram (cross-section) of the flexible wiring board test sample of Example 1.

FIG. 5 is a schematic diagram (cross-section) of a flex-rigid wiring board.

### DETAILED DESCRIPTION OF THE INVENTION

The present invention relates to a flexible wiring board for repeated folding sections, which comprises a wiring patterned base film layer (I), a flexible insulating material layer (II) covering the layer (I), and a cover film layer (III) covering the layer (II), as well as to a flex-rigid wiring board comprising the flexible wiring board.

The wiring patterned base film layer (I) of the invention has any desired conductive wiring pattern formed on a pliable insulating base material. There are no particular restrictions on the pliable insulating base material, and there may be used publicly known polyimide films, polyethylene terephthalate films, polyethylene naphthalate films, polytetrafluoroethylene films, polyamide films, polyarylate films, polysulfone films, polyethersulfone films, polysulfide films, polyetherimide films, polyetherketone films, polyamideimide films and liquid crystal polymer films, although polyimide films are preferred.

Any desired thickness is appropriate, but the thickness will usually be in the range of 5-125 μm, preferably in the range of 10-75 μm and most preferably in the range of 12-50 μm.

The wiring pattern is an electrical circuit formed of a conductive substance (for example, copper foil), and is produced by etching. The wiring patterned base film layer (I) may be manufactured by any desired process, such as forming a patterning resist on a commercially available copper-clad laminate, followed by steps of exposure, developing, etching and resist release.

For formation of the patterning resist, it is preferred to pretreat the surface of the copper-clad laminate by roughening treatment such as microetching, or blackening treatment. Such treatment may be carried out using a hydrogen peroxide-based, sulfuric acid-based, persulfate-based or chlorine-based treatment agent.

The flexible insulating material layer (II) of the invention is a layer made of an insulating material with a pliable property, and it has the function of covering the base film layer (I) to protect the wiring pattern. Together with the cover film layer (III), it also confers resistance to repeated folding to the flexible printed wiring board and flex-rigid wiring board of the invention.

The flexible wiring board for repeated folding sections according to the invention is conferred with suitable stiffness and flexibility due to the presence of the flexible insulating material layer (II). This prevents excessive bending of the wiring pattern made of the metal material such as copper as well as peeling from the base film, while also improving the resistance to repeated folding.

The flexible insulating material layer (II) of the invention preferably has a volume resistivity of 0.1 MΩ/cm² or greater.

From the standpoint of flexibility, the flexible insulating material layer (II) of the invention has a tensile modulus (JIS K7217) in the range of preferably 5-6000 MPa, more preferably 100-4000 MPa and even more preferably 300-2000 MPa. When the flexible insulating material layer (II) is a curable resin composition, the aforementioned values are the values after curing. The modulus of an ordinary cured epoxy resin is about 20,000 MPa, and therefore the modulus of the flexible insulating material layer of the invention is considerably low.

The thickness of the flexible insulating material layer (II) of the invention will normally be in the range of 1-500 μm, preferably in the range of 5-200 μm and most preferably in the range of 10-50 μm.

The material for the flexible insulating material layer (II) may be any one composed of a single compound, or a composition comprising a plurality of compounds. The flexible insulating material layer (II) is formed by any desired method on the base film layer (I) so as to cover the circuit pattern, and specifically, it may be formed by a method of coating a solution or dispersion of the flexible insulating material on the base and then drying it, or a method of contact bonding a film of the flexible material onto the base. Any desired contact bonding method may be employed for contact bonding, and publicly known apparatuses may be used without any restrictions whatsoever. The conditions employed may be any desired conditions achieved by appropriate adjustment of the roll temperature, roll pressure, etc. There are no particular restrictions on the application method, which may be any desired application method such as screen printing, bar coating, roll coating, spray coating, dip coating, curtain coating or the like, and the application conditions employed may also be any conditions which are commonly employed.

The cover film layer (III) of the invention is a resin film or metal foil layer formed so as to cover the layer (II), and it confers additional repeated folding endurance to the flexible printed wiring board and flex-rigid wiring board of the invention. The cover film layer (III) is formed by any desired process in a manner so as to cover a portion or the entirety of the layer (II), and for example, it may be formed by press bonding a commercially available cover-lay film using a laminating press or heat roll.

For manufacture of the flex-rigid wiring board, the cover film layer (III) may be formed on a single portion of the layer (II) in order to minimize usage of the cover film, in which case the cover film is preferably laminated in a later step in such a manner as to cover the regions formed by the rigid sections. This will further facilitate release of the cover film from the borders between the rigid and flexible sections and minimize interruption of the copper circuit at those sections. The parts of the laminated cover film formed on the regions formed by the rigid sections will be partially incorporated into the rigid sections by later steps.

The cover film used as the cover film layer (III) may be a polyimide film, polyethylene terephthalate film, polyethylene naphthalate film, polytetrafluoroethylene film, polyamide film, polyarylate film, polysulfone film, polyethersulfone film, polysulfide film, polyetherimide film, polyetherketone film, polyamideimide film, liquid crystal polymer film, acrylic resin film or the like, or any of these films whose surfaces have been vapor deposited with a metal such as aluminum or the like to provide an electromagnetic blocking function, or a metal foil such as aluminum foil. Polyimide films are preferred among these, and they may be in the form of cover-lay films having an adhesive layer. The cover film may also be laminated by bonding the cover film layer (III) onto the flexible insulating material layer (II) via an adhesive sheet, but an alternative is to use a flexible insulating material with an adhesive property in order to allow bonding of the cover film without requiring the use of an adhesive sheet or an adhesive agent. This is a preferred method because it can reduce the number of steps and lower the amount of material consumption.

The cover film layer (III) may additionally be covered by another flexible insulating material layer (II), as this will not only further improve the folding endurance but will also improve the moisture resistance. In addition, it provides the following advantages for formation of rigid sections in the manufacture of flex-rigid wiring boards.

(1) The flexible insulating material (II) may be used instead of a bonding sheet to form the rigid sections, and after laminating such members as copper-clad laminates or prepregs in a semi-cured state, they may be heated, etc. in order to simultaneously accomplish curing of the flexible insulating material and adhesion of the copper-clad laminates.

(2) All or a portion of the parts formed by the flexible sections and rigid sections may be covered with the layer (II) and cured, and then the layer (II) further coated onto the parts on which the rigid sections are formed for use instead of an adhesive agent or bonding sheet to form the rigid sections. In this case, the flexible insulating material (II) covering the cover film layer (III) and the flexible insulating material (II) coated as the adhesive agent for formation of the rigid sections are made of the same material, so that a flex-rigid wiring board with excellent adhesion reliability between the layers can be obtained.

(3) After forming the rigid sections by any desired method on the cover film (III), the conductor of the outermost layer of the rigid sections and the remaining flexible sections may be simultaneously covered with the flexible insulating material (II), thereby reducing the number of manufacturing steps. In this process, it is possible to simultaneously cover not only the rigid sections and flexible sections but also the edges of the rigid sections with the flexible insulating material, thereby allowing more inexpensive manufacture of a flex-rigid wiring board with highly reliable moisture resistance. In most cases, a level gradient will be present at the border between the rigid sections and flexible sections, and the coated flexible insulating material (II) will accumulate at the level gradient, thereby relieving stress concentrated at the border and providing a more highly reliable flex-rigid wiring board.

The flexible wiring board for repeated folding sections according to the invention comprises the layers (I), (II) and (III) described above, but other optional layers may also be formed thereon. In addition, the layers (II) and (III) may also be formed on the opposite side of the layer (I), or they may be formed as multilayers.

A flex-rigid wiring board according to the invention will now be explained. The flex-rigid wiring board of the invention may be fabricated by connecting a flexible wiring board comprising the layers (I), (II) and (III) described above with a rigid wiring board, or by forming a rigid wiring board on a portion of the aforementioned flexible wiring board.

More specifically, the flexible wiring board comprising the layers (I), (II) and (III) described above is treated with a solder resist, except for the portion constituting the flexible section. Next, a prepreg or another member is laminated onto the solder resist, or optionally a wiring pre-patterned rigid wiring board is mounted thereon, and throughholes, interstitial via holes or a circuit pattern may be formed therein by any desired method to form a rigid section. The solder resist used in this case may be of any desired type, but the solder resist is preferably made of the same material as the flexible insulating material of layer (II). An adhesive sheet or the like may be used for bonding when mounting a prepreg or another member, but if the layer (II) is in a pre-curing adhesive state, direct bonding can be accomplished without using an adhesive sheet. This is a preferred method because it can reduce the number of steps and lower the amount of material consumption.

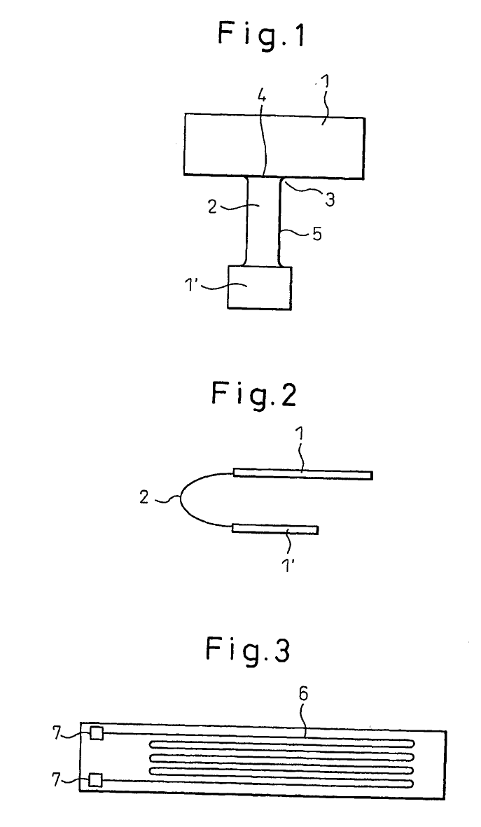

In a flex-rigid wiring board of the invention obtained in the manner described above, the flexible wiring board portion has a top edge 4 which connects with a rigid section and a side edge 5 which crosses therewith, as shown in FIG. 1, and the angle α of crossing between the top edge and side edge may be an acute angle in order to improve the breaking strength between the rigid wiring board and flexible wiring board. The portion 3 at the intersection of the top edge 4 and side edge 5 is most preferably an arc, from the viewpoint of the breaking strength. The arc may have any curvature radius, but it is most preferably 1.0 mm or greater from the viewpoint of improving the breaking strength.

According to the invention, several advantages are provided and satisfactory folding endurance is obtained as a result of the construction of the invention, and therefore the aforementioned specific substances are preferably used as the flexible insulating material. Flexible insulating materials preferred for use according to the invention will now be explained.

Such flexible insulating materials may be curing resins such as thermosetting resins or photosensitive resins, or their resin compositions, or non-curing resins such as thermoplastic resins, although curing resins are preferred. Particularly preferred curing resins include those comprising photosensitive resin compositions, from the standpoint of positioning precision for covering of the base film layer. When the flexible insulating material is a curable composition, the flexible insulating material layer (II) will be a cured product of the flexible insulating material.

A thermosetting resin composition is a resin composition which is itself curable by heat or a curing agent, and any publicly known one may be used without restriction. More specifically, it may be an epoxy resin, a phenol resin, a urea resin, a melamine resin, a diallyl phthalate resin, an epoxy acrylate resin obtained by addition of an unsaturated carboxylic acid to a polyvalent epoxy compound such as an epoxy resin, or an unsaturated polyester resin, alkyd resin or the like. Such thermosetting resin compositions may be publicly known ones, but those having a glass transition temperature (TMA method, JIS K7197) after curing in the range of 0-200° C., in the range of 20-150° C. and especially in the range of 30-100° C., are preferred from the standpoint of flexibility and folding endurance.

Publicly known curing agents for thermosetting resin may also be used, including amines, acid anhydrides and the like, for epoxy resins. For ethylenic unsaturated bond-containing resins such as epoxy acrylate resins and unsaturated polyester resins, there may be used organic peroxides such as dibenzoyl peroxide, dilauroyl peroxide, dicumyl peroxide and di-t-butyl peroxide, or azo compounds such as azobisisobutyronitrile.

Any publicly known photosensitive resin compositions may be used for the invention without restriction, and examples thereof include compositions comprising a curing resin (A-1), a photopolymerization initiator (B) and a diluent (C). Any of such publicly known photosensitive resin compositions may be used, but those having a glass transition temperature (TMA method, JIS K7197) after curing in the range of 0-200° C., further in the range of 20-150° C. and especially in the range of 30-100° C., are preferred from the standpoint of flexibility and folding endurance.

A photosensitive resin composition for the invention may also contain a non-polymerizable resin (A-2).

When a photosensitive resin composition is used as the flexible insulating material, the curing resin (A-1) used may be one obtained by addition of an unsaturated carboxylic acid to a polyvalent epoxy compound such as epoxy resin, or it may be one obtained by addition of an unsaturated epoxy compound to the carboxyl group of a (meth)acrylic acid/methacrylic acid ester copolymer, but it is preferably an unsaturated group-containing polycarboxylic acid resin (A′). Copolymers of (meth)acrylic acid and methacrylic acid may be mentioned as examples for the non-polymerizable resin (A-2).

The unsaturated group-containing polycarboxylic acid resin (A′) is a resin having at least one polymerizable unsaturated group and carboxyl group in the molecule, and it may be one obtained by, for example, addition of an unsaturated carboxylic acid to a polyvalent epoxy compound such as epoxy resin, followed by reaction with an acid anhydride, one obtained by addition of an unsaturated epoxy compound to a portion of the carboxyl groups of a (meth)acrylic acid-methacrylic acid ester copolymer, or one obtained by addition of an unsaturated hydroxy compound to a compound containing an acid anhydride group, such as a copolymer of styrene and maleic anhydride or itaconic anhydride. Preferred among these are unsaturated group-containing polycarboxylic acid resins which are reaction products of succinic anhydride (c) and the addition product of an epoxy resin (a) and an unsaturated group-containing monocarboxylic acid (b).

As specific examples of the unsaturated group-containing monocarboxylic acid (b) there may be mentioned half-esters which are reaction products of acrylic acid, acrylic acid dimers, methacrylic acid, β-styrylacrylic acid, β-furfurylacrylic acid, crotonic acid, α-cyanocinnamic acid, cinnamic acid and saturated or unsaturated dibasic acid anhydrides, with (meth)acrylate derivatives having one hydroxyl group in the molecule, or half-esters which are reaction products of saturated or unsaturated dibasic acids with unsaturated group-containing monoglycidyl compounds. Half-esters include, for example, half-esters obtained by reacting saturated and unsaturated dibasic acid anhydrides such as succinic anhydride, maleic anhydride, phthalic anhydride, tetrahydrophthalic anhydride, hexahydrophthalic anhydride, methylhexahydrophthalic anhydride, methyltetrahydrophthalic anhydride, itaconic anhydride or methylendomethylenetetrahydrophthalic anhydride in equimolar amounts with (meth)acrylate derivatives having one hydroxyl group in the molecule, such as hydroxyethyl (meth)acrylate, hydroxypropyl(meth)acrylate, hydroxybutyl(meth)acrylate, polyethyleneglycol mono(meth)acrylate, glycerin di(meth)acrylate, trimethylolpropane di(meth)acrylate, pentaerythritol tri(meth)acrylate, dipentaerythritol penta(meth)acrylate and phenyl glycidyl ether (meth)acrylates, or half-esters obtained by reacting saturated or unsaturated dibasic acids (for example, succinic acid, maleic acid, adipic acid, phthalic acid, tetrahydrophthalic acid, hexahydrophthalic acid, itaconic acid, fumaric acid, etc.) in equimolar ratios with unsaturated group-containing monoepoxy compounds (for example, glycidyl (meth)acrylate). Such unsaturated group-containing monocarboxylic acids (b) may be used alone or in combinations. Acrylic acid is a particularly preferred unsaturated group-containing monocarboxylic acid.

A carboxyl group-containing urethane (meth)acrylate compound is preferably obtained by reacting a hydroxyl group-containing (meth)acrylate (α), a polyol (β) and a polyisocyanate (γ).

The hydroxyl group-containing (meth)acrylate (a) is a compound which forms both ends of the carboxyl group-containing urethane (meth)acrylate compound, and as specific compounds there may be mentioned 2-hydroxyethyl (meth)acrylate, hydroxypropyl(meth)acrylate, hydroxybutyl(meth)acrylate, caprolactone or alkylene oxide addition products of the aforementioned (meth)acrylates, glycerin mono(meth)acrylate, glycerin di(meth)acrylate, glycidyl methacrylate-acrylic acid addition product, trimethylolpropane mono(meth)acrylate, trimethylol di(meth)acrylate, pentaerythritol tri(meth)acrylate, dipentaerythritol penta(meth)acrylate, ditrimethylolpropane tri(meth)acrylate, trimethylolpropane-alkylene oxide addition product-di(meth)acrylate, and the like.

These hydroxyl group-containing (meth)acrylates (a) may be used alone or in combinations. Preferred among these are 2-hydroxyethyl(meth)acrylate, hydroxypropyl (meth)acrylate and hydroxybutyl(meth)acrylate, with 2-hydroxyethyl(meth)acrylate being more preferred.

The polyol (β) is a compound which, together with the polyisocyanate (γ), constitutes the repeating unit of the carboxyl group-containing urethane (meth)acrylate compound, and there may be mentioned polymer polyols (β1) and carboxyl group-containing dihydroxyl compounds (β2).

As polymer polyols (β1) to be used for the invention there may be mentioned polyether-based diols such as polyethylene glycol, polypropylene glycol and polytetramethylene glycol, polyester-based polyols obtained from esters of polyhydric alcohols and polybasic acids, polycarbonate-based diols containing as constituent units a unit derived from hexamethylene carbonate, pentamethylene carbonate or the like, and polylactone-based diols such as polycaprolactone diols, polybutyrolactone diols and the like. These polymer polyols (β1) may also be used in combination with one or more polyols selected from among polyether-based diols, polyester-based diols, polycarbonate-based diols and polylactone-based diols. A carboxyl group may also be introduced into the polymer polyols. The number-average molecular weight of these polymer polyols (β1) is preferably 200-2000 from the standpoint of pliability.

In the range for a carboxyl group-containing dihydroxyl compound (β2) to be used for the invention, there are preferred dimethylolpropionic acid and dimethylolbutanoic acid which contain branched or straight-chain dihydroxy aliphatic carboxylic acids with at least two alcoholic hydroxyl groups.

As specific polyisocyanates (γ) to be used for the invention there may be mentioned diisocyanates such as 2,4-toluene diisocyanate, 2,6-toluenediisocyanate, isophorone diisocyanate, hexamethylene diisocyanate, diphenylmethylene diisocyanate, (o, m or p)-xylene diisocyanate, methylene bis(cyclohexylisocyanate), trimethylhexamethylene diisocyanate, cylcohexane-1,3-dimethylene diisocyanate, cyclohexane-1,4-dimethylene diisocyanate and 1,5-naphthalene diisocyanate. These polyisocyanates may be used alone or in combinations of two or more.

The carboxyl group-containing urethane (meth)acrylate compound used for the invention has ends composed of units derived from the hydroxyl group-containing (meth)acrylate (α), while the repeating unit between them is composed of the polyol (β) and polyisocyanate (γ) linked by urethane bonds and is represented by —(OR_{b}O—OCNHR_{c}NHCO)ₙ— [wherein OR_{b}O represents the dehydrogenated residue of the polyol (β) and R_{c} represents the deisocyanated residue of the polyisocyanate (γ)], and n, representing the number of repeating units, is preferably about 1-200, and more preferably 2-30.

When the repeating unit comprises two or more different components for either or both the polyol (β) and polyisocyanate (γ) there will be a plurality of different repeating units, in which case the iteration scheme of the repeating units may be appropriately selected to be totally random, block or localized, depending on the purpose.

There are no particular restrictions on the method used to produce the carboxyl group-containing urethane (meth)acrylate compound to be used for the invention from the hydroxyl group-containing (meth)acrylate (α), polyol (β) and polyisocyanate (γ), and as preferred production processes there may be mentioned a process of mixing the (meth)acrylate (α), polyol (β) and polyisocyanate (γ) together at once for reaction, a process of reacting the (β) component and (γ) component to form a urethane isocyanate prepolymer containing one or more isocyanate groups per molecule and then reacting the urethane isocyanate prepolymer with the (α) component, and a process of reacting the (α) component and (γ) component to form a urethane isocyanate prepolymer containing one or more isocyanate groups per molecule and then reacting the prepolymer with the (β) component.

The photopolymerization initiator (B) is a compound with the ability to initiate polymerization of unsaturated bonds by irradiation with ultraviolet rays or the like, and any publicly known ones may be used. There may be used, for example, benzoins such as benzoin, benzoin methyl ether and benzoin isopropyl ether, acetophenones such as acetophenone, 2,2-dimethoxy-2-phenylacetophenone, 2,2-diethoxy-2-phenylacetophenone, 1,1-dichloroacetophenone, 1-hydroxycyclohexylphenyl ketone, 2-methyl-1-[4-(methylthio)phenyl]-2-morpholino-propan-1-one and N,N-dimethylaminoacetophenone, anthraquinones such as 2-methylanthraquinone, 2-ethylanthraquinone, 2-tert-butylanthraquinone, 1-chloroanthraquinone, 2-amylanthraquinone and 2-aminoanthraquinone, thioxanthones such as 2,4-dimethylthioxanthone, 2,4-diethylthioxanthone, 2-chlorothioxanthone and 2,4-diisopropylthioxanthone, ketals such as acetophenonedimethylketal and benzyldimethylketal, benzophenones such as benzophenone, methylbenzophenone, 4,4′-dichlorobenzophenone, 4,4′-bisdiethylaminobenzophenone, Michler's ketone and 4-benzoyl-4′-methyldiphenyl sulfide and 2,4,6-trimethylbenzoyldiphenylphosphine oxide. These may be used alone or in combinations of two or more, and preferred are combinations of 2-methyl-1-[4-(methylthio)phenyl]-2-morpholino-propan-1-one (IRGACURE 907, by Ciba-Geigy) with 2,4-diethylthioxanthone (KAYACURE DETX, by Nippon Kayaku Co., Ltd.), 2-isopropylthioxanthone or 4-benzoyl-4′-methyldiphenyl sulfide.

In addition, the photopolymerization initiator (B) may also employ photosensitizers including tertiary amines such as N,N-dimethylaminobenzoic acid ethyl ester, N,N-dimethylaminobenzoic acid isoamyl ester, pentyl 4-dimethylaminobenzoate, triethylamine and triethanolamine, either alone or in combinations of two or more.

The photopolymerization initiator (B) may be used in any proportion in the photosensitive resin composition, but the proportion will usually be 0.5-20 wt % and preferably 1-10 wt %.

As diluents (C) there may be used publicly known solvents and/or photopolymerizable monomers. As representative solvents there may be mentioned ketones such as ethyl methyl ketone and cyclohexanone, aromatic hydrocarbons such as toluene, xylene and tetramethylbenzene, glycol ethers such as methylcellosolve, butylcellosolve, methylcarbitol, butylcarbitol, propyleneglycol monomethyl ether, dipropyleneglycol monoethyl ether, dipropyleneglycol diethyl ether and triethyleneglycol monoethyl ether, esters such as ethyl acetate, butyl acetate, butylcellosolve acetate and carbitol acetate, alcohols such as ethanol, propanol, ethylene glycol and propylene glycol, aliphatic hydrocarbons such as octane and decane, and petroleum-based solvents such as petroleum ether, petroleum naphtha, hydrogenated petroleum naphtha and solvent naphtha. For reduced flammability, water may be used as the solvent. When water is used as the solvent, the (A′) component is preferably dissolved in the water by converting the carboxyl group in the (A′) component to a salt with an amine such as trimethylamine or triethylamine, or a (meth)acrylate compound with a tertiary amino group, such as N,N-dimethylaminoethyl (meth)acrylate, N,N-dimethylaminopropyl(meth)acrylamide, N,N-dimethyl(meth)acrylamide, acryloylmorpholine, N-isopropyl (meth)acrylamide or N-methylolacrylamide.

As specific examples of photopolymerizable monomers there may be mentioned hydroxyalkyl(meth)acrylates such as 2-hydroxyethyl(meth)acrylate and 2-hydroxypropyl (meth)acrylate, mono or di(meth)acrylates of glycols such as ethylene glycol, methoxytetraethylene glycol and polyethylene glycol, (meth)acrylamides such as N,N-dimethyl (meth)acrylamide and N-methylol (meth)acrylamide, aminoalkyl(meth)acrylates such as N,N-dimethylaminoethyl (meth)acrylate, polyhydric (meth)acrylates of polyhydric alcohols such as hexanediol, trimethylolpropane, pentaerythritol, ditrimethylolpropane, dipentaerythritol and tris-hydroxyethyl isocyanurate, or of their ethylene oxide or propylene oxide addition products, (meth)acrylates of ethylene oxide or propylene oxide addition products of phenols, such as phenoxyethyl(meth)acrylate or polyethoxy di(meth)acrylate of bisphenol A′, (meth)acrylates of glycidyl ethers such as glycerin diglycidyl ether, trimethylolpropane triglycidyl ether and triglycidyl isocyanurate, ε-caprolactone-modified (meth)acrylates such as caprolactone-modified tris(acryloyloxyethyl)isocyanurate, melamine (meth)acrylates, and the like.

These diluents (C) may be used alone or in mixtures of two or more. The amount of diluent (C) in the photosensitive resin composition of the invention is preferably 5-80 wt % and more preferably 10-70 wt % in the composition.

The photosensitive resin composition of the invention is most preferably used as an ordinary solder resist. It also preferably contains a curable component (D) in addition to the unsaturated group-containing polycarboxylic acid resin (A′) (which is, for example, the reaction product of succinic anhydride (c) with the addition product of an epoxy resin (a) and an unsaturated group-containing monocarboxylic acid (b)), the photopolymerization initiator (B) and the diluent (C).

As specific examples of curable components (D) there may be mentioned compounds which have no unsaturated double bonds and are themselves cured by heat or ultraviolet light, and compounds which react under heat or ultraviolet light with the carboxyl group of the (A′) component which is the main component of the flexible insulating material. As specific examples there may be mentioned epoxy compounds having one or more epoxy groups in the molecule (for example, bisphenol A-type epoxy resins such as EPIKOTE 1009, 1031 by Japan Epoxy Resins Co., Ltd., EPICLON N-3050, N-7050 by Dainippon Ink and Chemicals, Inc. and DER-642U, DER-673MF by The Dow Chemical Co., hydrogenated bisphenol A-type epoxy resins such as ST-2004, ST-2007 by Touto Kasei, KK., bisphenol F-type epoxy resins such as YDF-2004, YDF-2007 by Touto Kasei, KK., brominated bisphenol A-type epoxy resins such as SR-BBS, SR-TBA-400 by Sakamoto Yakuhin Kogyo Co., Ltd. and YDB-600, YDB-715 by Touto Kasei, KK., novolac-type epoxy resins such as EPPN-201, EOCN-103, EOCN-1020, BREN by Nippon Kayaku Co., Ltd., bisphenol A novolac-type epoxy resins such as EPICLON N-880 by Dainippon Ink and Chemicals, Inc., amino group-containing epoxy resins such as YL-931, YL-933 by Yuka-Shell Epoxy Co. Ltd., rubber-modified epoxy resins such as EPICLON TSR-601 by Dainippon Ink and Chemicals, Inc. and R-1415-1 by Asahi Denka Co., Ltd., bisphenol S-type epoxy resins such as EBPS-200 by Nippon Kayaku Co., Ltd. and EPICLON EXA-1514 by Dainippon Ink and Chemicals, Inc., diglycidyl terephthalate such as BLEMER DGT by NOF Corp., triglycidyl isocyanurate such as TEPIC by Nissan Chemical Industries, Ltd., bixylenol-type epoxy resins (biphenol-type epoxy resins) such as YX-4000 by Yuka-Shell Epoxy Co., Ltd., bisphenol-type epoxy resins such as YL-6056 by Yuka-Shell Epoxy Co., Ltd., alicyclic epoxy resins such as CELLOXIDE 2021 by Daicel Chemical Industries, Ltd.), melamine derivatives (for example, hexamethoxymelamine, hexabutoxylated melamine and condensed hexamethoxymelamine), urea compounds (for example, dimethylolurea, etc.), bisphenol A-based compounds (for example, tetramethylol-bisphenol A, etc.), oxazoline compounds, and the like.

There may also be used urethane acrylates having a urethane backbone and a polymerizable unsaturated bond in the molecule (for example, U-4HA, U-15HA, U-108A, UA-122P, U-200AX, UA-4100, UA-4400, UA-340P, UA-2235PE, UA-160TM, UA-6100, etc. by Shin-Nakamura Chemical Corp.)

Preferred among these are epoxy compounds having one or more epoxy groups per molecule, with bisphenol-type or biphenol-type epoxy resins being preferred, and biphenol-type epoxy resins being most preferred.

The purpose of using the curable component (D) is to further increase the properties such as cohesion, heat resistance and plating resistance. One curable component (D) may be used alone or two or more of them may be used in combination, and the amount of the curable component (D) in the composition of the invention is preferably 1-50 wt % and most preferably 3-45 wt %.

When an epoxy compound is used in the curable component (D), a curing agent for epoxy resin is preferably used in combination therewith in order to further improve the properties such as cohesion, chemical resistance, heat resistance and the like. As specific examples of curing agents for epoxy resin there may be mentioned common publicly known curing agents or curing accelerators, including imidazole derivatives (2MZ, 2E4MZ, C₁₁Z, C₁₇Z, 2PZ, 1B2MZ, 2MZ-CN, 2E4MZ-CN, C₁₁Z-CN, 2PZ-CN, 2PHZ-CN, 2MZ-CNS, 2E4MZ-CNS, 2PZ-CNS, 2MZ-A′ ZINE, 2E4MZ-A′ ZINE, C₁₁Z-A′ ZINE, 2MA′-OK, 2P4MHZ, 2PHZ, 2P4BHZ by Shikoku Corp.); guanamines such as acetoguanamine and benzoguanamine; polyamines such as diaminodiphenylmethane, m-phenylenediamine, m-xylenediamine, diaminodiphenylsulfone, dicyandiamide, urea, urea derivatives, melamine and polybasic hydrazides; organic acid salt and/or epoxy adducts of these; amine complexes of boron trifluoride; triazine derivatives such as ethyldiamino-S-triazine, 2,4-diamino-S-triazine and 2,4-diamino-6-xylyl-s-triazine;

tertiary amines such as trimethylamine, triethanolamine, N,N-dimethyloctylamine, N-benzyldimethylamine, pyridine, N-methylmorpholine, hexa(N-methyl)melamine, 2,4,6-tris(dimethylaminophenol), tetramethylguanidine and m-aminophenol; polyphenols such as polyvinylphenol, brominated polyvinylphenol, phenol novolac and alkylphenol novolacs; organic phosphines such as tributylphosphine, triphenylphosphine and tris-2-cyanoethylphosphine; phosphonium salts such as tri-n-butyl (2,5-dihydroxyphenyl)phosphonium bromide and hexadecyltributylphosphonium chloride; tertiary ammonium salts such as benzyltrimethylammonium chloride and phenyltributylammonium chloride; the aforementioned polybasic acid anhydrides;

photocationic polymerization catalysts such as diphenyliodonium tetrafluoroborate, triphenylsulfonium hexafluoroantimonate, 2,4,6-triphenylthiopyrilium hexafluorophosphate, IRGACURE 261 by Ciba Geigy, OPTOMER SP-170 by Asahi Denka Co., Ltd.; styrene-maleic anhydride resins; and equimolar mixtures of phenyl isocyanate and dimethylamine or equimolar mixtures of organic polyisocyanates such as tolylene diisocyanate or isophorone diisocyanate, and dimethylamine; these may be used either alone or in combinations of two or more. The amounts of such epoxy resin curing agents used are preferably 0.01-25 parts by weight and more preferably 0.1-15 parts by weight with respect to 100 parts by weight of the epoxy compound.

The flexible insulating material of the invention may further contain common publicly known inorganic fillers such as barium sulfate, barium titanate, silicon oxide powder, fined powdered silicon oxide, amorphous silica, talc, clay, magnesium carbonate, calcium carbonate, aluminum oxide, aluminum hydroxide, mica powder and the like, for the purpose of improving the properties such as cohesion and hardness, depending on the need. The amounts thereof used in the flexible insulating material are preferably 0-60 wt % and more preferably 5-40 wt %.

If necessary, common publicly known additives may also be used, including common publicly known coloring agents such as phthalocyanine blue, phthalocyanine green, iodine green, disazo yellow, crystal violet, titanium oxide, carbon black and naphthalene black, common publicly known polymerization inhibitors such as hydroquinone, hydroquinone monomethyl ether, tert-butylcatechol, pyrogallol and phenothiazine, common publicly known thickeners such as asbestos, olben, bentone and montmorillonite, silicone-based, fluorine-based and high-molecular antifoaming agents, and/or leveling agents and cohesion agents such as imidazole-based, thiazole-based or triazole-based silane coupling agents, among which silicone-containing compounds are preferred from the standpoint of cohesion of the cover film.

There may also be used common publicly known binder resins including copolymers of ethylenic unsaturated compounds such as acrylic acid esters, or polyester resins synthesized from polyhydric alcohols and polybasic acid compounds, as well as photopolymerizable oligomers such as polyester (meth)acrylates, polyurethane (meth)acrylates and epoxy(meth)acrylates, in ranges which do not hinder the gist of the invention.

Any desired process may be employed for production of the composition for the flexible insulating material, and it may be produced by a publicly known process such as mixture of the components in the aforementioned proportions and uniform blending with a roll mill or the like.

### EXAMPLES

Fabrication and Evaluation of Flexible Wiring Board Test Samples

1) Fabrication of Flexible Wiring Board Test Samples

A flexible wiring board test sample was fabricated for a folding test by the steps described below. FIG. 3 shows schematic diagram of a test sample. The test sample was in a 150 mm×15 mm rectangular shape, and the wiring pattern section was approximately 110 mm×10 mm. The line/space ratio of the wiring pattern section was 0.1/0.1 mm, and electrodes were provided at two locations on the edge. A repeating folding test was conducted by repeatedly folding the test sample in the lengthwise direction. Circuit breakage at any point of the wiring during the test interrupted the current flowing between the electrodes and was detectable as a break.

Step 1:

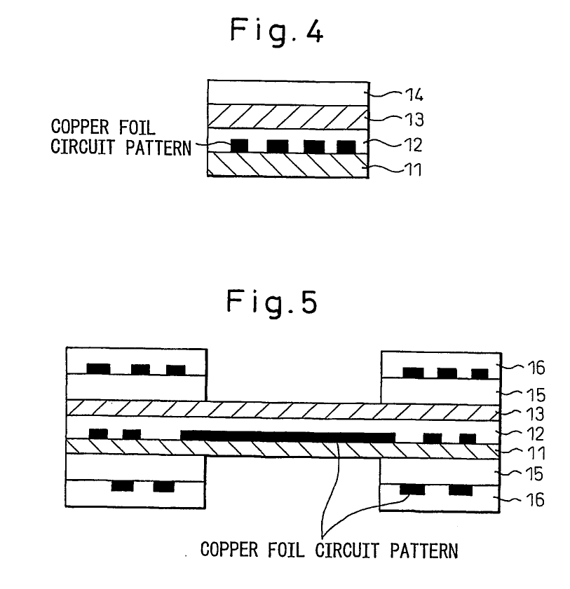

After press bonding a dry film resist onto a commercially available copper-clad laminate (R-F775 by Matsushita Electric Works, Ltd., 25 μm-thick polyimide film laminated on one side with 18 μm rolled copper foil), the laminate was subjected to photomask exposure, developing, etching and release steps to fabricate a wiring pattern-formed base film layer (I) (FIG. 4, reference numeral 11).

Step 2:

The base film layer (I) obtained in Step 1 above was coated with a prescribed flexible insulating material composition by screen printing (using a 100 mesh polyester screen) so as to cover the circuit pattern, and then after drying the film for 30 minutes with a hot air drier at 80° C., the entire surface was exposed to ultraviolet rays (ultra-high pressure mercury lamp, 365 nm dominant wavelength, 400 mJ/cm²) to fabricate a 40 μm-thick flexible insulating material layer (II) (FIG. 4, reference numeral 12).

Step 3:

The total surface of the flexible printed wiring board fabricated in Step 2 above was laminated with a polyimide cover-lay film (T-type by Toray, 25 μm-thick polyimide film coated with 8 μm-thick adhesive) as the cover film layer (III) (FIG. 4, reference numeral 13) and rolled bonded therewith to fabricate a flexible wiring board.

Step 4:

The total surface of the flexible wiring board fabricated in Step 3 above was coated with the same flexible insulating material composition used for Step 2 by screen printing, and the same procedure was carried out as in Step 2 to form a 40 μm-thick layer (FIG. 4, reference numeral 14) (see FIG. 4). The resultant layer was then post-cured at 150° C. for 30 minutes.

2) Synthesis of Unsaturated Bond-Containing Polycarboxylic Acid Resin

After dissolving 371 parts of a bisphenol A-type epoxy resin having 650 epoxy equivalents, a softening point of 81.1° C. and a melting point (150° C.) of 12.5 poise in 925 parts of epichlorhydrin and 462.5 parts of dimethylsulfoxide, the solution was stirred while adding 52.8 parts of 98.5% NaOH over a period of 100 minutes at 70° C. After the addition, reaction was conducted at 70° C. for 3 hours. The excess unreacted epichlorhydrin and most of the dimethylsulfoxide were distilled off under reduced pressure, the reaction product comprising a byproduct salt and dimethylsulfoxide was dissolved in 750 parts of methyl isobutyl ketone, and then 10 parts of 30% NaOH was added and reaction was conducted at 70° C. for 1 hour. Upon completion of the reaction, the product was washed twice with 200 g of water. After oil/water separation, the methyl isobutyl ketone was distilled off, and there was recovered from the oil layer 340 g of an epoxy resin having 287 epoxy equivalents, a hydrolyzable chlorine content of 0.07%, a softening temperature of 64.2° C. and a melting point (150° C.) of 0.71 Pa·s.

After charging 2870 parts (10 equivalents) of an epoxy resin obtained in the manner described above, 720 parts (10 equivalents) of acrylic acid, 2.8 parts of methylhydroquinone and 1943.5 parts of carbitol acetate, the mixture was heated to 90° C. and stirred for dissolution of the reaction mixture. The reaction solution was then cooled to 60° C., 16.6 parts of triphenylphosphine was charged in and the mixture was heated to 100° C. for reaction for approximately 32 hours to obtain a mixture with an acid value of 1.0 mgKOH/g. After then charging in 783 parts (7.83 moles) of succinic anhydride and 421.6 parts of carbitol acetate and heating to 95° C. for reaction for approximately 6 hours, the solvent was distilled off to obtain an unsaturated group-containing polycarboxylic acid resin with an acid value of 100 mgKOH/g.

3) Cohesion Test

A 1-mm square grid (100 squares) was prepared in a flexible wiring board test sample for fold testing, and a peeling test was conducted with cellophane tape according to JIS K5400. The appearance of the grids after peeling was observed and evaluated on the following scale:

⊚: At least 91 grids without peeling

◯: 81-90 grids without peeling

Δ: 50-80 grids without peeling

x: Less than 50 grids without peeling

4) Folding Endurance Test

A commercially available MIT flexibility evaluation tester (by Tester Sangyo, KK.) was used for testing according to JIS P8115, and the number of folds was counted up to cracking and breaking. The curvature radius of the folding surface was 2.0 mm, the refraction cycle was 175/min, the refraction angle was 135° on both sides and the load was 4.5 N.

5) Glass Transition Temperature Tg

The Tg was defined as the discontinuity of the linear expansion coefficient, according to TMA (thermomechanical analysis, JIS K7197). The measuring apparatus was a model TMA-SS6100 by Seiko Instruments Co., Ltd.

### Examples 1 and 2

The components listed in Table 1 below were used for fabrication of flexible wiring board test samples in the manner described above. The results are shown in Table 1.

TABLE 1

| | | | | Comp. | | Comp. | | | | | |
|---|---|---|---|---|---|---|---|---|---|---|---|
| | | Example 1 | Example 2 | Ex. 1 | Example 3 | Ex. 2 | Example 4 | Example 5 | Example 6 | Example 7 | Example 8 |
| KAYARAD | pts. by wt. | 50 | — | 50 | 50 | 50 | — | 50 | 35 | 15 | — |
| ZBR *1 | | | | | | | | | | | |
| KAYARAD | pts. by wt. | — | — | — | — | — | — | — | — | — | 50 |
| PCR *2 | | | | | | | | | | | |
| Unsaturated | pts. by wt. | — | 50 | — | — | — | 50 | — | — | — | — |
| group-containing | | | | | | | | | | | |
| polycarboxylic acid | | | | | | | | | | | |
| resin obtained in | | | | | | | | | | | |
| synthesis example | | | | | | | | | | | |
| U-200AX *3 | pts. by wt. | 5 | 5 | 5 | 5 | 5 | 5 | 5 | 20 | 40 | 5 |
| IRGACURE 907 *4 | pts. by wt. | 5 | 5 | 5 | 5 | 5 | 5 | 5 | 5 | 5 | 5 |
| Silica | pts. by wt. | 8 | 8 | 8 | 8 | 8 | 8 | 8 | 8 | 8 | 8 |
| AEROSIL 200 | pts. by wt. | 1 | 1 | 1 | 1 | 1 | 1 | 1 | 1 | 1 | 1 |
| Dicyandiamide | pts. by wt. | 0.5 | 0.5 | 0.5 | 0.5 | 0.5 | 0.5 | 0.5 | 0.5 | 0.5 | 0.5 |
| EPIKOTE YX4000 | pts. by wt. | 10 | 10 | 10 | 10 | 10 | 10 | 10 | 10 | 10 | 10 |
| Silicone-based | pts. by wt. | — | — | — | — | — | — | 0.5 | 0.5 | 0.5 | 0.5 |
| antifoaming agent | | | | | | | | | | | |
| Diethyleneglycol | pts. by wt. | 20.5 | 20.5 | 20.5 | 20.5 | 20.5 | 20.5 | 20 | 20 | 20 | 20 |
| monoethylether | | | | | | | | | | | |
| acetate | | | | | | | | | | | |
| Total | pts. by wt. | 100 | 100 | 100 | 100 | 100 | 100 | 100 | 100 | 100 | 100 |
| Glass | ° C. | 110 | 92 | 110 | 110 | 110 | 110 | 110 | 70 | 27 | 128 |
| transition | | | | | | | | | | | |
| temperature | | | | | | | | | | | |
| Step 2 | | + | + | − | + | + | + | + | + | + | + |
| Step 3 | | + | + | + | + | − | + | + | + | + | + |
| Step 4 | | + | + | + | − | − | − | + | + | + | + |
| Flexibility | ×1000 times | 168 | 172 | 7 | 162 | 12 | 160 | 141 | 156 | 130 | 98 |
| Cover film cohesion | | ⊚ | ⊚ | Δ | ⊚ | — | ⊚ | ◯ | ◯ | Δ | ◯ |

*1: Reaction product of succinic anhydride with hydroxyl groups of bisphenol A-type epoxy acrylate (contained 24.5 wt % carbitol acetate and 10.5 wt % solvent naphtha, solid acid value: 100 mgKOH/g), Nippon Kayaku Co., Ltd.
*2: Reaction product of succinic anhydride with phenol novolac-type epoxy acrylate (reaction product of acrylic acid with EPPN-201, product of Nihon Kayaku Co., Ltd.) (contained 24.5 wt % carbitol acetate and 10.5 wt % solvent naphtha, solid acid value: 100 mgKOH/g), Nippon Kayaku Co., Ltd.
*3: Urethane acrylate, Shin-Nakamura Chemical Corp.
*4: Photopolymerization initiator, 2-methyl-[4-(methylthio)phenyl]-2-morpholino-1-propanone, Chiba Specialty Chemicals
*5: Nippon Aerosil Co., Ltd.
*6: Bixylenol-type epoxy resin, Japan Epoxy Resins Co., Ltd.

### Comparative Example 1

The method “1) Fabrication of flexible wiring board test samples” described above was carried out in the same manner as Example 1, except that Step 2 was eliminated.

### Examples 3 and 4

Example 1 was carried out in the same manner, except that Step 4 was eliminated. The results are shown in Table 1.

### Comparative Example 2

Example 1 was carried out in the same manner, except that Steps 3 and 4 were eliminated. The results are shown in Table 1.

### Examples 5-8

Example 1 was carried out in the same manner, except that the components listed in Table 1 were used. The results are shown in Table 1.

### Examples 9-13

Example 1 was carried out in the same manner, except that the components listed in Table 2 below were used. In Steps 2 and 4, drying with a hot air drier and exposure to ultraviolet rays were not conducted. In Step 2, after coated, the layer was cured at 150° C. for 30 minutes. The results are shown in Table 2.

TABLE 2

| | | | Example | Example | Example | Example |
|---|---|---|---|---|---|---|
| | | Example 9 | 10 | 11 | 12 | 13 |
| EPIKOTE 1004 *1 | pts. by wt. | — | 60 | 40 | 20 | 60 |
| EPPN-201 *2 | pts. by wt. | 60 | — | — | — | — |
| TSR-601 *3 | pts. by wt. | 5 | 5 | 25 | 45 | 5 |
| Silica | pts. by wt. | 10 | 10 | 10 | 10 | 10 |
| AEROSIL 200 *4 | pts. by wt. | 1 | 1 | 1 | 1 | 1 |
| 2-Ethyl-4-methylimidazole | pts. by wt. | 3 | 3 | 3 | 3 | 3 |
| Dicyandiamide | pts. by wt. | 0.5 | 0.5 | 0.5 | 0.5 | 0.5 |
| Silicone-based antifoaming agent | pts. by wt. | — | — | — | — | 0.5 |
| Diethyleneglycol monoethylether acetate | pts. by wt. | 20 | 20 | 20 | 20 | 20.5 |
| Total | pts. by wt. | 100 | 100 | 100 | 100 | 100 |
| Glass transition temperature | ° C. | 127 | 105 | 64 | 30 | 106 |
| Step 2 | | + | + | + | + | + |
| Step 3 | | + | + | + | + | + |
| Step 4 | | + | + | + | + | + |
| Flexibility | ×1000 times | 87 | 135 | 122 | 115 | 113 |
| Cover film cohesion | | Δ | ⊚ | ⊚ | ⊚ | ◯ |

*1: Bisphenol A-type epoxy resin, Japan Epoxy Resins Co., Ltd.
*2: Phenol novolac-type epoxy resin, Nippon Kayaku Co., Ltd.
*3: Rubber-modified epoxy resin, Dainippon Ink and Chemicals, Inc.
*4: Nippon Aerosil Co., Ltd.

Fabrication and Evaluation of Flex-Rigid Wiring Board
6) Fabrication of Flex-Rigid Wiring Board

A flex-rigid wiring board having the shape shown in FIG. 1 was fabricated by the steps described below.

Step 1:

After press bonding a dry film resist onto a commercially available copper-clad laminate (R-F775 by Matsushita Electric Works, Ltd., 25 μm-thick polyimide film laminated on one side with 18 μm rolled copper foil), the laminate was subjected to photomask exposure, developing, etching and release steps to fabricate a base film layer (I) having a wiring pattern formed on one side thereof (FIG. 5, reference numeral 11).

Step 2:

The base film layer (I) obtained in Step 1 above was coated with a prescribed flexible insulating material composition by screen printing (using a 100 mesh polyester screen) so as to cover the circuit pattern, and then after drying the film for 30 minutes with a hot air drier at 80° C., the entire surface was exposed to ultraviolet rays (ultra-high pressure mercury lamp, 365 nm dominant wavelength, 400 mJ/cm²) to fabricate a 40 μm-thick flexible insulating material layer (II) (FIG. 5, reference numeral 12).

Step 3:

The total surface of the flexible printed wiring board fabricated in Step 2 above was laminated with a polyimide cover-lay film (T-type by Toray, 25 μm-thick polyimide film coated with 8 μm-thick adhesive) as the cover film layer (III) (FIG. 5, reference numeral 13) and contact bonded therewith to fabricate a flexible wiring board.

Step 4:

Next, both sides of a portion of the flexible wiring board fabricated in Step 3 above were laminated with a 100 μm-thick prepreg for multilayer laminate and an 18 μm-thick copper foil, and bonding was accomplished with a hot press at 180° C. to form rigid sections.

Step 5:

The metal layers of the rigid sections fabricated in Step 4 above were etched to form a circuit pattern (FIG. 5, reference numeral 15), and then coated with a solder resist to a thickness of 40 μm by screen printing (FIG. 5, reference numeral 16) to fabricate a flex-rigid wiring board (see FIG. 5).

### Examples 14-16

Using the same component composition and flexible section layer construction as in Example 3, the process described above was carried out to fabricate flex-rigid wiring boards wherein the shape of the section 3 at the intersection between the bottom edge 4 of the rigid section 1 and the side edge 5 of the flexible section 2 in FIG. 1 had arcs with curvature radii of 0.5 mm, 1.5 mm and 2.0 mm, respectively. The rigid sections of each of the obtained wiring boards were horizontally anchored with clamps, the flexible section was situated perpendicular to the rigid sections, and a load was placed on the flexible section for measurement of the load required for breakage. The loads causing breakage between the rigid sections and flexible sections were 120 gf, 600 gf and 720 gf, respectively.

### Comparative Examples 3-5

Flex-rigid wiring boards having arcs with curvature radii of 0.5 mm, 1.5 mm and 2.0 mm were fabricated in the same manner as Examples 15-17, except that Step 2 was eliminated for fabrication of the flex-rigid wiring boards. The loads causing breakage between the rigid sections and flexible sections were 50 gf, 120 gf and 180 gf, respectively.

### Examples 17-19

Using the same component composition and flexible section layer construction as in Example 1, flex-rigid wiring boards having arcs with curvature radii of 0.5 mm, 1.5 mm and 2.0 mm were fabricated in the same manner as Examples 14-16, except that Step 4-1 below was carried out instead of Step 4. The loads causing breakage between the rigid sections and flexible sections were 150 gf, 720 gf and 830 gf, respectively.

Step 4-1:

The total surfaces of both sides of the flexible printed wiring board fabricated in Step 3 above were coated with a prescribed flexible insulating material composition by screen printing (using a 100 mesh polyester screen), and then after drying the coated film for 30 minutes with a hot air drier at 80° C., the entire surface was exposed to ultraviolet rays (ultra-high pressure mercury lamp, 365 nm dominant wavelength, 400 mJ/cm²) to fabricate a 40 μm-thick flexible insulating material layer (II) on a cover film layer (III).

Both sides of a portion of the flexible printed wiring board fabricated in this manner were laminated with a 100 μm-thick prepreg for multilayer laminate and an 18 μm-thick copper foil, and bonding was carried out with a hot press at 180° C. to form rigid sections.

### EFFECT OF THE INVENTION

According to the invention, it is possible to manufacture a flexible wiring board with excellent repeated folding endurance and a flex-rigid wiring board comprising the flexible wiring board as a section thereof, which are useful as flexible printed wiring boards linked by repeated movable sections of folding cellular phones, notebook computers and the like.

List of Reference Numerals

1,1′ Rigid sections
2 Flexible section
3 Intersection
4 Lower edge of rigid section
5 Side edge of flexible section
6 Pattern circuit
7 Electrode
11 Base film layer (I) (containing copper foil circuit pattern section)
12 Flexible insulating material layer (II)
13 Cover film layer (III)
14 Flexible insulating material layer
15 Prepreg cured layer (containing copper foil circuit pattern section)
16 Solder resist layer

1. A flexible wiring board for repeated folding sections, which comprises a wiring patterned base film layer (I), a flexible insulating material layer (II) covering (I), and a cover film layer (III) covering (II).

2. The flexible wiring board for repeated folding sections according to claim 1, wherein the cover film layer (III) is further covered with a flexible insulating material.

3. The flexible wiring board for repeated folding sections according to claim 1, characterized in that said flexible insulating material layer (II) is a cured heat-curing and/or photocuring resin composition.

4. The flexible wiring board for repeated folding sections according to claim 3, characterized in that said heat-curing and/or photocuring resin composition contains a biphenol-type epoxy resin.

5. The flexible wiring board for repeated folding sections according to claim 4, characterized in that said heat-curing and/or photocuring resin composition contains an urethane acrylate.

6. The flexible wiring board for repeated folding sections according to claim 1, wherein said base film layer (I) is a polyimide.

7. The flexible wiring board for repeated folding sections according to claim 1, wherein said cover film layer (III) is a polyimide film.

8. The flexible wiring board for repeated folding sections according to claim 7, wherein said cover film layer (III) is an adhesive-attached polyimide film.

9. A flex-rigid wiring board provided with a flexible wiring board for repeated folding sections which comprises a wiring patterned base film layer (I), a flexible insulating material layer (II) covering (I), and a cover film layer (III) covering (II).

10. A flex-rigid wiring board having a rigid section formed on a portion of a flexible wiring board for repeated folding sections which comprises a wiring patterned base film layer (I), a flexible insulating material layer (II) covering (I), and a cover film layer (III) covering (II).

11. The flex-rigid wiring board according to claim 10, wherein said cover film layer (III) forms part of the rigid section.

12. The flex-rigid wiring board according to claim 10, wherein said rigid section is formed so as to cover a portion of the cover film layer (III).

13. The flex-rigid wiring board according to claim 9, wherein said cover film layer (III) is further covered with a flexible insulating material.

14. The flex-rigid wiring board provided with a flexible wiring board for repeated folding sections according to claim 1.

15. The flex-rigid wiring board according to claim 10, wherein said cover film layer (III) is further covered with a flexible insulating material.

16. The flex-rigid wiring board provided with a flexible wiring board for repeated folding sections according to claim 2.
